(19) United States
(12) Patent Application Publication
(10) Pub. No.: US 2025/0160129 A1
(43) Pub. Date: May 15, 2025

(54) DISPLAY DEVICE

(71) Applicant: Samsung Display Co., Ltd., Yongin-Si (KR)

(72) Inventors: Jin Taek KIM, Yongin-si (KR); Suk Hoon KU, Yongin-si (KR); Yong Tae CHO, Yongin-si (KR); Sang Yeol KIM, Yongin-si (KR); Jung Tae PARK, Yongin-si (KR); Chun Gi YOU, Yongin-si (KR)

(21) Appl. No.: 18/824,910

(22) Filed: Sep. 5, 2024

(30) Foreign Application Priority Data
Nov. 13, 2023 (KR) 10-2023-0156656

(51) Int. Cl. H10K 59/122; H10K 50/19; H10K 102/00

(52) U.S. Cl. CPC H10K 59/122; H10K 50/19; H10K 2102/351

(57) ABSTRACT

A display device is disclosed that includes: pixels each including emission areas and a non-emission area adjacent to the emission areas, and a pixel defining layer overlapping the non-emission area. The pixel defining layer includes trenches enclosing the respective emission areas and spaced apart from each other. A corner of each of the trenches is chamfered.

### CROSS-REFERENCE TO RELATED APPLICATION(S)

The application claims priority to Korean Patent Application No. 10-2023-0156656, filed on Nov. 13, 2023, and all the benefits accruing therefrom under 35 U.S.C. § 119, the content of which in its entirety is herein incorporated by reference.

### BACKGROUND

### 1. Field

The present disclosure relates to a display device.

### 2. Description of the Related Art

With the development of information technology, the importance of a display device, which is a connection medium between a user and information, has been emphasized. Owing to the importance of display devices, the use of various kinds of display devices, such as a liquid crystal display device and an organic light-emitting display device, has increased.

### SUMMARY

Embodiments may provide a display device capable of preventing lateral leakage current, disconnection of a cathode electrode, and defects in an encapsulation layer.

An embodiment of a display device includes: pixels each including emission areas and a non-emission area adjacent to the emission areas, and a pixel defining layer overlapping the non-emission area, the pixel defining layer including trenches enclosing the respective emission areas and spaced apart from each other. A corner of each of the trenches may be chamfered.

An inner corner and an outer corner of each of the trenches may be chamfered.

A width of an edge of each of the trenches may be identical to a width of the corner of each of the trenches.

The width may range from 80 nm to 150 nm.

A thickness of each of the trenches may range from 300 nm to 1000 nm.

A distance between the trenches may range from 100 nm to 300 nm.

A corner of each of the emission areas may be chamfered.

A corner of each of the emission areas may be right-angled.

An inner corner of each of the trenches may be right-angled, and an outer corner of each of the trenches may be chamfered.

A width of an edge of each of the trenches may be identical to a width of the corner of each of the trenches.

The width of the edge of each of the trenches may be less than a maximum width between the inner corner and the outer corner of each of the trenches.

A width of an edge of each of the trenches may be different from a width of the corner of each of the trenches.

The width of the edge of each of the trenches may be greater than the width of the corner of each of the trenches.

The width of the edge of each of the trenches may be identical to a maximum width between the inner corner and the outer corner of each of the trenches.

The emission areas may include a first emission area configured to emit light in a first color, a second emission area configured to emit light in a second color, and a third emission area configured to emit light in a third color.

The first emission area and the second emission area may be arranged in a first direction, and the third emission area may be arranged in a second direction with respect to the first emission area and the second emission area.

The display device may further include: anode electrodes to which openings of the pixel defining layer extend, an emission structure disposed on the anode electrodes and the pixel defining layer, and a cathode electrode disposed on the emission structure.

The emission structure may include: a first emission component including a first hole transport component, a first electron transport component, and a first emission layer disposed between the first hole transport component and the first electron transport component, a second emission component including a second hole transport component, a second electron transport component, and a second emission layer disposed between the second hole transport component and the second electron transport component, and a charge generation layer disposed between the first emission component and the second emission component.

The charge generation layer may include a discontinuous portion overlapping at least a portion of each of the trenches.

The cathode electrode may be continuously disposed on the emission structure.

### BRIEF DESCRIPTION OF THE DRAWINGS

The above and other features of embodiments of the present disclosure will become more apparent by describing in further detail embodiments thereof with reference to the accompanying drawings.

FIG. 1 is a block diagram schematically illustrating a display device in accordance with an embodiment.

FIG. 2 is a block diagram schematically illustrating a sub-pixel in accordance with an embodiment.

FIG. 3 is a plan view schematically illustrating a display panel in accordance with an embodiment.

FIG. 4 is an exploded perspective view illustrating a portion of the display panel of FIG. 3.

FIG. 5 is a sectional view schematically illustrating an emission structure in accordance with an embodiment.

FIG. 6 is a sectional view schematically illustrating an emission structure in accordance with an embodiment.

FIG. 7 is a plan view schematically illustrating a pixel in accordance with an embodiment.

FIG. 8 is a plan view schematically illustrating a display device including pixels of FIG. 7.

FIG. 9 is a sectional view schematically illustrating the display device of FIG. 8.

FIG. 10 is a plan view schematically illustrating a pixel in accordance with an embodiment.

FIG. 11 is a plan view schematically illustrating a display device including pixels of FIG. 10.

FIG. 12 is an enlarged view of an intersection area of FIG. 11.

FIG. 13 is a sectional view taken along line I-I′ of FIG. 11.

FIG. 14 is a sectional view schematically illustrating the display device of FIG. 11.

FIG. 15 is a plan view schematically illustrating a display device including pixels of FIG. 7.

FIG. 16 is an enlarged view of the intersection area of FIG. 15 in accordance with an embodiment.

FIG. 17 is an enlarged view of the intersection area of FIG. 15 in accordance with an embodiment.

FIG. 18 is a block diagram illustrating a display system in accordance with an embodiment.

FIG. 19 is a perspective diagram illustrating an application example of the display system of FIG. 18.

FIG. 20 is a diagram illustrating a head mounted display device of FIG. 19 that is worn on a user.

### DETAILED DESCRIPTION OF THE ILLUSTRATED EMBODIMENTS

Embodiments will now be described more fully hereinafter with reference to the accompanying drawings, in which the various embodiments are shown. The inventive concepts may, however, be embodied in many different forms, and should not be construed as limited to the embodiments set forth herein. Rather, these embodiments are provided so that this disclosure will be thorough and complete, and will fully convey the scope of the inventive concepts to those skilled in the art.

Like numbers refer to like elements throughout. In the drawings, the thickness of certain lines, layers, components, elements or features may be exaggerated for clarity. It will be understood that, although the terms “first”, “second”, etc. may be used herein to describe various elements, these elements should not be limited by these terms. These terms are only used to distinguish one element from another element. Thus, a “first” element discussed below could also be termed a “second” element.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” As used herein, the word “or” means logical “or” so that, unless the context indicates otherwise, the expression “A, B, or C” means “A and B and C,” “A and B but not C,” “A and C but not B,” “B and C but not A,” “A but not B and not C,” “B but not A and not C,” and “C but not A and not B.”

It will be further understood that the terms “comprises,” “comprising,” “includes,” and “including”, when used in this specification, specify the presence of stated features, integers, steps, operations, elements, or components, but do not preclude the presence or addition of one or more other features, integers, steps, operations, elements, components, or groups thereof.

In the entire specification, when an element is referred to as being “connected” or “coupled” to another element, it can be directly connected or coupled to the another element or be indirectly connected or coupled to the another element with one or more intervening elements interposed therebetween.

Furthermore, relative terms, such as “lower” or “bottom” and “upper” or “top,” may be used herein to describe one element's relationship to another element as illustrated in the figures. It will be understood that relative terms are intended to encompass different orientations of the device in addition to the orientation depicted in the figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Hereinafter, embodiments will be described in detail with reference to the accompanying drawings.

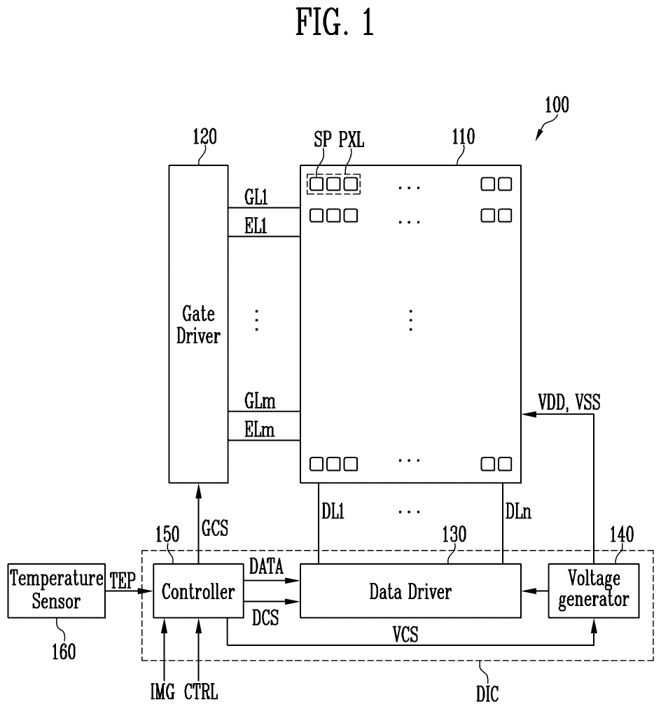

FIG. 1 is a block diagram schematically illustrating a display device 100 in accordance with an embodiment.

Referring to FIG. 1, the display device 100 may include a display panel 110, a gate driver 120, a data driver 130, a voltage generator 140, and a controller 150.

The display panel 110 may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

Each of the sub-pixels SP may include at least one light emitting element configured to generate light. Accordingly, each of the sub-pixels SP may generate light in a specific color such as red, green, blue, cyan, magenta, or yellow. Two or more sub-pixels among the sub-pixels SP may form one pixel PXL. For example, as illustrated in FIG. 1, three sub-pixels SP may form one pixel PXL.

The gate driver 120 may be connected to sub-pixels SP arranged in a row direction through the first to m-th gate lines GL1 to GLm. The gate driver 120 may output gate signals to the first to m-th gate lines GL1 to GLm in response to a gate control signal GCS. In embodiments, the gate control signal GCS may include a start signal instructing each frame to start, a horizontal synchronization signal for outputting gate signals in synchronization with a timing at which data signals are applied, and the like.

In embodiments, there may be further provided first to m-th emission control lines EL1 to ELm connected to the sub-pixels SP in the row direction. In this case, the gate driver 120 may include an emission control driver configured to control the first to m-th emission control lines EL1 to ELm. The emission control driver may operate under the control of the controller 150.

The gate driver 120 may be disposed on one side of the display panel 110. However, embodiments are not limited to the aforementioned example. For example, the gate driver 120 may be divided into two or more drivers that are physically and/or logically distinguished from each other. The drivers may be disposed on a first side of the display panel 110 and a second side of the display panel 110 opposite to the first side. As such, the gate driver 120 may be disposed around the display panel 110 in various forms depending on embodiments.

The data driver 130 may be connected to sub-pixels SP arranged in a column direction through the first to n-th data lines DL1 to DLn. The data driver 130 may receive image data DATA and a data control signal DCS from the controller 150. The data driver 130 may operate in response to the data control signal DCS. In embodiments, the data control signal DCS may include a source start pulse, a source shift clock, a source output enable signal, and the like.

The data driver 130 may apply, using voltages from the voltage generator 140, data signals having grayscale voltages corresponding to the image data DATA to the first to n-th data lines DL1 to DLn. When a gate signal is applied to each of the first to m-th gate lines GL1 to GLm, data signals corresponding to the image data DATA may be applied to the first to n-th data lines DL1 to DLn. Hence, the corresponding sub-pixels SP may generate light corresponding to the data signals. As a result, an image may be displayed on the display panel 110.

In embodiments, the gate driver 120 and the data driver 130 may include complementary metal-oxide semiconductor (CMOS) circuit elements.

The voltage generator 140 may operate in response to a voltage control signal VCS provided from the controller 150. The voltage generator 140 is configured to generate a plurality of voltages and provide the generated voltages to components of the display device 100. For example, the voltage generator 140 may receive an input voltage from an external device provided outside the display device 100, adjust the received voltage, and regulate the adjusted voltage, thus generating a plurality of voltages.

The voltage generator 140 may generate a first power voltage VDD and a second power voltage VSS. The generated first and second power voltages VDD and VSS may be provided to the sub-pixels SP. The first power voltage VDD may have a relatively high voltage level. The second power voltage VSS may have a voltage level lower than the first power voltage VDD. In other embodiments, the first power voltage VDD or the second power voltage VSS may be provided by an external device of the display device 100.

In addition, the voltage generator 140 may generate various voltages. For example, the voltage generator 140 may generate an initialization voltage to be applied to the sub-pixels SP. For example, during a sensing operation for sensing electrical characteristics of transistors and/or light emitting elements of the sub-pixels SP, a certain reference voltage may be applied to each of the first to n-th data lines DL1 to DLn. The voltage generator 140 may generate the reference voltage. The controller 150 may control overall operations of the display device 100.

The controller 150 may receive input image data IMG and a control signal CTRL for controlling an operation of displaying the input image data IMG from an external device. The controller 150 may provide the gate control signal GCS, the data control signal DCS, and the voltage control signal VCS, in response to the control signal CTRL. The controller 150 may convert the input image data IMG to be suitable for the display device 100 or the display panel 110 and thus output image data DATA. In embodiments, the controller 150 may align the input image data IMG to be suitable for the sub-pixels SP on a row basis and then output the image data DATA.

Two or more components of the data driver 130, the voltage generator 140, and the controller 150 may be mounted into a single integrated circuit. As illustrated in FIG. 1, the data driver 130, the voltage generator 140, and the controller 150 may be included in a driver integrated circuit DIC. In this case, the data driver 130, the voltage generator 140, and the controller 150 may be components that are functionally separated from each other in the single driver integrated circuit DIC. In other embodiments, at least one of the data driver 130, the voltage generator 140, and the controller 150 may be provided as a component separated from the driver integrated circuit DIC.

The display device 100 may include at least one temperature sensor 160. The temperature sensor 160 is configured to sense a peripheral temperature and generate temperature data TEP indicating the sensed temperature. In embodiments, the temperature sensor 160 may be disposed adjacent to the display panel 110 and/or the driver integrated circuit DIC.

The controller 150 may control various operations of the display device 100 in response to the temperature data TEP. In embodiments, the controller 150 may adjust the luminance of an image outputted from the display panel 110 in response to the temperature data TEP. For example, the controller 150 may control components such as the data driver 130 and/or the voltage generator 140, thus adjusting data signals and the first and second power voltages VDD and VSS.

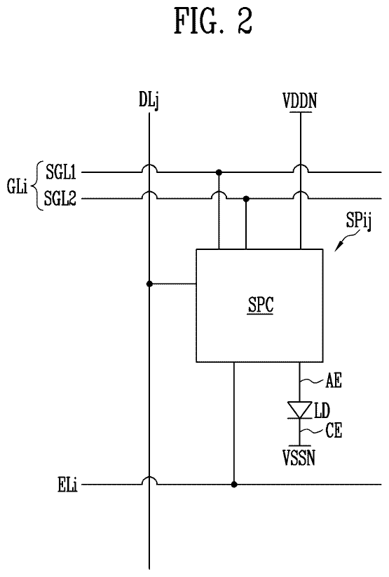

FIG. 2 is a block diagram schematically illustrating a sub-pixel SPij in accordance with an embodiment. In FIG. 2, there is illustrated the sub-pixel SPij disposed on an i-th row (where i is an integer identical to or greater than 1 and identical to or less than m) and a j-th column (where j is an integer identical to or greater than 1 and identical to or less than n).

Referring to FIG. 2, the sub-pixel SPij may include a sub-pixel circuit SPC and a light emitting element LD.

The light emitting element LD is connected between a first power voltage node VDDN and a second power voltage node VSSN. Here, the first power voltage node VDDN may be a node provided to transmit the first power voltage VDD of FIG. 1. The second power voltage node VSSN may be a node provided to transmit the second power voltage VSS.

An anode electrode AE of the light emitting element LD may be connected to the first power voltage node VDDN through the sub-pixel circuit SPC. A cathode electrode CE of the light emitting element LD may be connected to the second power voltage node VSSN. For example, the anode electrode AE of the light emitting element LD may be connected to the first power voltage node VDDN through one or more transistors included in the sub-pixel circuit SPC.

The sub-pixel circuit SPC may be connected to an i-th gate line GLi among the first to m-th gate lines GL1 to GLm of FIG. 1, an i-th emission control line ELi among the first to m-th emission control lines EL1 to ELm of FIG. 1, and a j-th data line DLj among the first to n-th data lines DL1 to DLn of FIG. 1. The sub-pixel circuit SPC is configured to control the light emitting element LD in response to signals received through the aforementioned signal lines.

The sub-pixel circuit SPC may operate in response to a gate signal received through the i-gate line GLi. The i-th gate line GLi may include one or more sub-gate lines. In embodiments, as illustrated in FIG. 2, the i-th gate line GLi may include first and second sub-gate lines SGL1 and SGL2. The sub-pixel circuit SPC may operate in response to gate signals received through the first and second sub-gate lines SGL1 and SGL2. As such, in the case where the i-th gate line GLi include two or more sub-gate lines, the sub-pixel circuit SPC may operate in response to gate signals received through the corresponding sub-gate lines.

The sub-pixel circuit SPC may operate in response to an emission control signal received through the i-emission control line ELi. In embodiments, the i-th emission control line ELi may include one or more sub-emission control lines. In the case where the i-th emission control line ELi include two or more sub-emission control lines, the sub-pixel circuit SPC may operate in response to emission control signals received through the corresponding sub-emission control lines.

The sub-pixel circuit SPC may receive a data signal through a j-th data line DLj. The sub-pixel circuit SPC may store a voltage corresponding to the data signal in response to at least one of gate signals received through the first and second sub-gate lines SGL1 and SGL2. The sub-pixel circuit SPC may adjust current flowing from the first power voltage node VDDN to the second power voltage node VSSN through the light emitting element LD according to the stored voltage, in response to the emission control signal received through the i-th emission control line ELi. Therefore, the light emitting element LD may emit light at a luminance corresponding to the data signal.

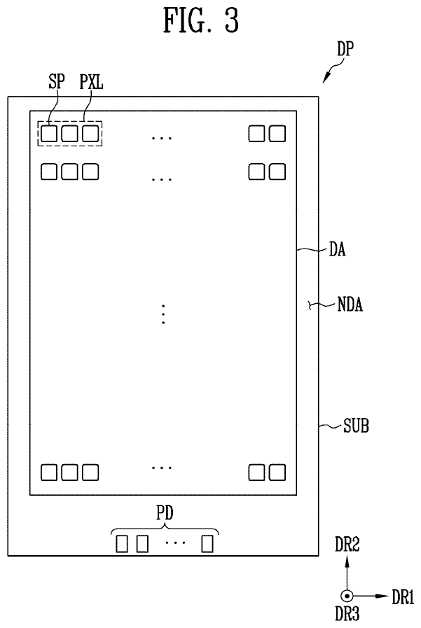

FIG. 3 is a plan view schematically illustrating a display panel DP in accordance with an embodiment.

Referring to FIG. 3, an embodiment of the display panel 110 depicted in FIG. 1 may include the display panel DP including a display area DA and a non-display area NDA. The display panel DP may display an image through the display area DA. The non-display area NDA may be disposed around the display area DA.

The display panel DP may include a substrate SUB, sub-pixels SP, and pads PD.

In the case where the display panel DP is used as a display screen for a head mounted display (HMD), a virtual reality (VR) device, a mixed reality (MR) device, an augmented reality (AR) device, and the like, the display panel DP may be positioned extremely close to the eyes of the user. In this case, relatively high-density sub-pixels SP may be required. To increase the pixel density of the sub-pixels SP, the substrate SUB may be provided as a silicon substrate. The sub-pixels SP and/or the display panel DP may be formed on the substrate SUB that is a silicon substrate. The display device 100 (refer to FIG. 1) including the display panel DP formed on the substrate SUB that is a silicon substrate may be referred to as an OLED on Silicon (OLEDoS) display device.

The sub-pixels SP may be disposed in the display area DA on the substrate SUB. The sub-pixels SP may be arranged in the form of a matrix along a first direction DR1 and a second direction DR2 intersecting with the first direction DR1. However, embodiments are not limited to the aforementioned example. For example, the sub-pixels SP may be arranged in a zigzag pattern in the first direction DR1 and the second direction DR2. For example, the sub-pixels SP may be arranged in the form of a PENTILE™. The first direction DR1 may refer to a row direction, and the second direction DR2 may refer to a column direction.

Two or more sub-pixels among the sub-pixels SP may form one pixel PXL.

Components for controlling the sub-pixels SP may be disposed in the non-display area NDA on the substrate SUB. For example, connected to the sub-pixels SP, lines such as the first to m-th gate lines GL1 to GLm and the first to n-th data lines DL1 to DLn of FIG. 1 may be disposed in the non-display area NDA.

At least one of the gate driver 120, the data driver 130, the voltage generator 140, the controller 150, and the temperature sensor 160 of FIG. 1 may be integrated in the non-display area NDA of the display panel DP. In embodiments, the gate driver 120 of FIG. 1 may be mounted on the display panel DP and positioned in the non-display area NDA. In other embodiments, the gate driver 120 may be implemented as an integrated circuit separated from the display panel DP. In embodiments, the temperature sensor 160 may be positioned in the non-display area NDA to sense the temperature of the display panel DP.

The pads PD may be disposed in the non-display area NDA on the substrate SUB. The pads PD may be electrically connected to the sub-pixels SP through the lines. For example, the pads PD may be connected to the sub-pixels SP through the first to n-th data lines DL1 to DLn.

The pads PD may interface the display panel DP with other components of the display device 100 (refer to FIG. 1). In embodiments, voltages and signals required for the operation of the components included in the display panel DP may be provided through the pads PD from the driver integrated circuit DIC of FIG. 1. For example, the first to n-th data lines DL1 to DLn may be connected to the driver integrated circuit DIC through the pads PD. For example, the first and second power voltages VDD and VSS may be received from the driver integrated circuit DIC through the pads PD. For example, in the case where the gate driver 120 is mounted on the display panel DP, the gate control signal GCS may be transmitted from the driver integrated circuit DIC to the gate driver 120 through the pads PD.

In embodiments, a circuit board may be electrically connected to the pads PD by a conductive adhesive component such as an anisotropic conductive film. Here, the circuit board may be a flexible circuit board or flexible film that is made of flexible material. The driver integrated circuit DIC may be mounted on the circuit board and be electrically connected to the pads PD.

In embodiments, the display area DA may have various shapes. The display area DA may have a closed-loop shape, including linear and/or curved sides. For example, the display area DA may have shapes such as polygons, circles, semicircles, ellipses, and the like.

In embodiments, the display panel DP may have a planar display surface. In embodiments, the display panel DP may have a display surface that is least partially rounded. In embodiments, the display panel DP may be bendable, foldable, or rollable. In the aforementioned cases, the display panel DP and/or the substrate SUB may include materials having flexible properties.

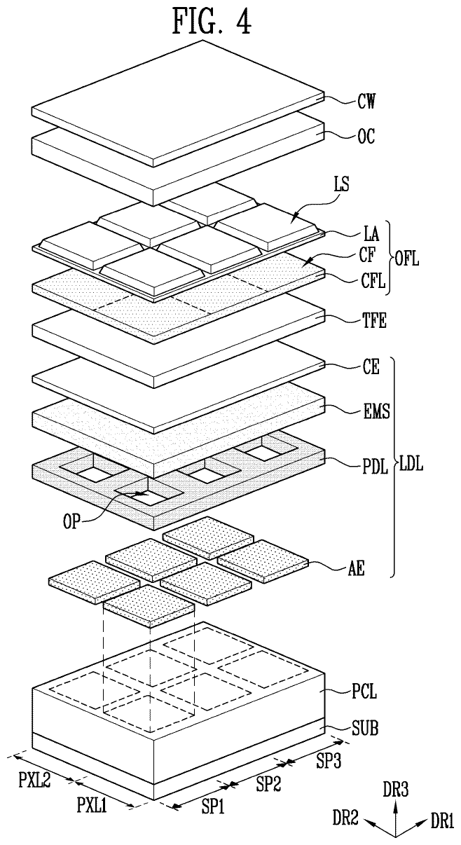

FIG. 4 is an exploded perspective view illustrating a portion of the display panel DP of FIG. 3. In FIG. 4, for the sake of clear and concise explanation, there is schematically illustrated a portion of the display panel DP corresponding to two pixels PXL1 and PXL2 among the pixels PXL of FIG. 3. The remaining portions of the display panel DP corresponding to the other pixels may also be configured in the same manner.

Referring to FIGS. 3 and 4, each of the first and second pixels PXL1 and PXL2 may include first to third sub-pixels SP1, SP2, and SP3. However, embodiments are not limited to the aforementioned example. For example, each of the first and second pixels PXL1 and PXL2 may include four sub-pixels, or may include two sub-pixels.

In FIG. 4 there is illustrated the case where the first to third sub-pixels SP1, SP2, and SP3 have rectangular shapes and the same size when viewed in a third direction DR3 intersecting with the first and second directions DR1 and DR2. However, embodiments are not limited to the aforementioned example. The first to third sub-pixels SP1, SP2, and SP3 may be modified to have various shapes.

The display panel DP may include a substrate SUB, a pixel circuit layer PCL, a light-emitting-element layer LDL, an encapsulation layer TFE, an optical functional layer OFL, an overcoat layer OC, and a cover window CW.

In embodiments, the substrate SUB may include a silicon wafer substrate formed through a semiconductor process. The substrate SUB may include semiconductor material suitable for forming circuit elements. For example, the semiconductor material may include silicon, germanium, and/or silicon-germanium. The substrate SUB may be provided from a bulk wafer, an epitaxial layer, a silicon on insulator (SOI) layer, a semiconductor on insulator (SeOl) layer, or the like. In embodiments, the substrate SUB may include a glass substrate. In embodiments, the substrate SUB may include a polyimide (polyimide) substrate.

The pixel circuit layer PCL may be disposed on the substrate SUB. The substrate SUB and/or the pixel circuit layer PCL may include insulating layers, and conductive patterns disposed between the insulating layers. The conductive patterns of the pixel circuit layer PCL may function as at least some of the circuit components, lines, or the like. The conductive patterns may include copper, but embodiments are not limited thereto.

The circuit elements may include respective sub-pixel circuits SPC (refer to FIG. 2) of the first to third sub-pixels SP1, SP2, and SP3. The sub-pixel circuit SPC may include transistors and one or more capacitors. Each transistor may include a semiconductor portion including a source area, a drain area, and a channel area, and a gate electrode overlapping the semiconductor portion. In embodiments, in the case where the substrate SUB is formed of a silicon substrate, the semiconductor portion may be included in the substrate SUB, and the gate electrode may be included in the pixel circuit layer PCL as a conductive pattern of the pixel circuit layer PCL. In an embodiment, in the case where the substrate SUB is formed of a glass substrate or a PI substrate, the semiconductor portion and the gate electrode may be included in the pixel circuit layer PCL. Each capacitor may include electrodes spaced apart from each other. For example, each capacitor may include electrodes spaced apart from each other on a plane defined in the first and second directions DR1 and DR2. For example, each capacitor may include electrodes spaced apart from each other in the third direction DR3 with an insulating layer interposed therebetween.

The lines of the pixel circuit layer PCL may include signal lines connected to each of the first to third sub-pixels SP1, SP2, and SP3, for example, a gate line, an emission control line, and a data line. The lines may further include a line connected to the first power voltage node VDDN of FIG. 2. Furthermore, the lines may further include a line connected to the second power voltage node VSSN of FIG. 2.

The light-emitting-element layer LDL may include anode electrodes AE, a pixel defining layer PDL, an emission structure EMS, and a cathode electrode CE.

The anode electrodes AE may be disposed on the pixel circuit layer PCL. The anode electrodes AE may contact circuit elements of the pixel circuit layer PCL. The anode electrodes AE may include opaque conductive material capable of reflecting light, but embodiments are not limited thereto.

The pixel defining layer PDL may be disposed on the anode electrodes AE. The pixel defining layer PDL may include openings OP that extend to and expose respective portions of the anode electrodes AE. The openings OP in the pixel defining layer PDL may be understood as respective emission areas corresponding to the first to third sub-pixels SP1 to SP3.

In embodiments, the pixel defining layer PDL may include inorganic material. In this case, the pixel defining layer PDL may include a plurality of inorganic layers stacked on top of one another. For example, the pixel defining layer PDL may include silicon oxide (SiOₓ) and silicon nitride (SiNₓ). In an embodiment, the pixel defining layer PDL may include organic material. However, the material of the pixel defining layer PDL is not limited to the aforementioned examples.

The emission structure EMS may be disposed on the anode electrodes AE exposed through the openings OP in the pixel defining layer PDL. The emission structure EMS may include an emission layer configured to generate light, an electron transport layer configured to transport electrons, and a hole transport layer configured to transport holes.

In embodiments, the emission structure EMS may fill the openings OP in the pixel defining layer PDL and be disposed on an overall surface of an upper portion of the pixel defining layer PDL. In other words, the emission structure EMS may extend over the first to third sub-pixels SP1 to SP3. In this case, at least some of the layers in the emission structure EMS may be interrupted or bent on boundaries between the first to third sub-pixels SP1 to SP3. However, embodiments are not limited to the aforementioned example. For instance, portions of the emission structure EMS corresponding to the first to third sub-pixels SP1 to SP3 may be separated from each other, and each may be disposed in the corresponding opening OP in the pixel defining layer PDL.

The cathode electrode CE may be disposed on the emission structure EMS. The cathode electrode CE may extend over the first to third sub-pixels SP1 to SP3. As such, the cathode electrode CE may be provided as a common electrode for the first to third sub-pixels SP1 to SP3.

The cathode electrode CE may be a thin-film metal layer having a thickness allowing light emitted from the emission structure EMS to pass therethrough. The cathode electrode CE may be made of a metal material having a relatively small thickness, or a transparent conductive material. In embodiments, the cathode electrode CE may include at least one of various transparent conductive materials including indium tin oxide, indium zinc oxide, indium tin zinc oxide, aluminum zinc oxide, gallium zinc oxide, zinc tin oxide, or gallium tin oxide. In embodiments, the cathode electrode CE may include at least one of silver (Ag), magnesium (Mg), and a compound thereof. However, the material of the cathode electrode CE is not limited to the foregoing example.

Any one of the anode electrodes AE, a portion of the emission structure EMS that overlap the any one anode electrode AE, and a portion of the cathode electrode CE that overlaps the portion of the emission structure EMS can be understood as constituting one light emitting element LD (refer to FIG. 2). In other words, each of the light emitting elements of the first to third sub-pixels SP1 to SP3 may include one anode electrode AE, a portion of the emission structure EMS that overlaps the one anode electrode AE, and a portion of the cathode electrode CE that overlaps the portion of the emission structure. In each of the first to third sub-pixels SP1 to SP3, holes injected from the anode electrode AE and electrons injected from the cathode electrode CE are transported into the emission layer of the emission structure EMS, thus forming excitons. When the excitons make a transition from an excited state to a ground state, light can be generated. Depending on the amount of current flowing through the emission layer, the luminance of light may be determined. Depending on the configuration of the emission layer, the wavelength range of light to be generated may be determined.

The encapsulation layer TFE may be disposed on the cathode electrode CE. The encapsulation layer TFE may cover the light-emitting-element layer LDL and/or the pixel circuit layer PCL. The encapsulation layer TFE may be configured to prevent oxygen and/or water or the like from penetrating into the light-emitting-element layer LDL. In embodiments, the encapsulation layer TFE may include a structure formed by alternately stacking one or more inorganic layers and one or more organic layers. For example, the inorganic layer may include silicon nitride, silicon oxide, silicon oxynitride (SiOxNy), or the like. For example, the organic layer may include organic insulating material such as acrylic resin, epoxy resin, phenol resin, polyamide resin, polyimide resin, unsaturated polyester resin, polyphenylenether resin, polyphenylenesulfide resin, or benzocyclobutene (BCB). However, the materials of the organic layer and the inorganic layer of the encapsulation layer TFE are limited to the aforementioned examples.

The encapsulation layer TFE may further include a thin film, including aluminum oxide (AIOx), to enhance the encapsulation efficiency of the encapsulation layer TFE. The thin film including aluminum oxide may be positioned on an upper surface of the encapsulation layer TFE that faces the optical functional layer OFL and/or under a lower surface of the encapsulation layer TFE that faces the light-emitting-element layer LDL.

The thin film including aluminum oxide may be formed through an atomic layer deposition (ALD) method. However, embodiments are not limited to the aforementioned example. The encapsulation layer TFE may further include a thin film formed of at least one of various materials suitable for enhancing the encapsulation efficiency.

The optical functional layer OFL may be disposed on the encapsulation layer TFE. The optical functional layer OFL may include a color filter layer CFL and a lens array LA.

The color filter layer CFL may be disposed between the encapsulation layer TFE and the lens array LA. The color filter layer CFL may be configured to filter light emitted from the emission structure EMS to selectively output light in a wavelength range or color corresponding to each sub-pixel. The color filter layer CFL may include color filters CF respectively corresponding to the first to third sub-pixels SP1 to SP3. Each of the color filters CF allows light within a wavelength range corresponding to the related sub-pixel to pass therethrough. For example, the color filter that corresponds to the first sub-pixel SP1 allows light in a red color to pass therethrough, the color filter that corresponds to the second sub-pixel SP2 allows light in a green color to pass therethrough, and the color filter that corresponds to the third sub-pixel SP3 allows light in a blue color to pass therethrough. Depending on the light emitted from the emission structure EMS of each sub-pixel, at least some of the color filters CF may be omitted.

The lens array LA may be disposed on the color filter layer CFL. The lens array LA may include lenses LS that respectively correspond to the first to third sub-pixels SP1 to SP3. Each of the lenses LS may output and direct light emitted from the emission structure EMS along an intended path, thus enhancing the light output efficiency. The lens array LA may have a relatively high refractive index. For example, the lens array LA may have a higher refractive index than the overcoat layer OC. In embodiments, the lenses LS may include organic material. In embodiments, the lenses LS may include acrylic material. However, the material of the lenses LS is not limited to the foregoing example.

In embodiments, compared to the openings OP of the pixel defining layer PDL, at least some of the color filters CF of the color filter layer CFL and at least some of the lenses LS of the lens array LA may be shifted in a direction parallel to the plane defined in the first and second directions DR1 and DR2. Specifically, in a central area of the display area DA, the center of each color filter and the center of each lens may be aligned or overlapped with the center of the corresponding opening OP of the pixel defining layer PDL. For example, in the central area of the display area DA, each opening OP of the pixel defining layer PDL may completely overlap the corresponding color filter of the color filter layer CFL and the corresponding lens of the lens array LA.

In an area of the display area DA that is adjacent to the non-display area NDA, the center of the color filter and the center of the lens LS may be shifted in a plane direction from the center of the corresponding opening OP of the pixel defining layer PDL when viewed in the third direction DR3. For example, in the area adjacent to the non-display area NDA within the display area DA, each opening OP of the pixel defining layer PDL may partially overlap the corresponding color filter of the color filter layer CFL and the corresponding lens of the lens array LA. Accordingly, light emitted from the emission structure EMS in the central portion of the display area DA may be efficiently outputted in the normal direction of the display surface. Light emitted from the emission structure EMS around the perimeter of the display area DA may be efficiently outputted in a direction inclined at a certain angle with respect to the normal direction of the display surface.

The overcoat layer OC may be disposed on the lens array LA. The overcoat layer OC may cover the optical functional layer OFL, the encapsulation layer TFE, the emission structure EMS, and/or the pixel circuit layer PCL. The overcoat layer OC may include various materials suitable for protecting underlying layers from foreign substances such as dust, water, or the like. For example, the overcoat layer OC may include at least one of an inorganic insulating layer and an organic insulating layer. For example, the overcoat layer OC may include epoxy, but it is not limited thereto. The overcoat layer OC may have a lower refractive index than the lens array LA.

The cover window CW may be disposed on the overcoat layer OC. The cover window CW may be configured to protect underlying layers. The cover window CW may have a higher refractive index than the overcoat layer OC. The cover window CW may include glass, but embodiments are not limited thereto. For example, the cover window CW may be an encapsulation glass layer configured to protect components disposed thereunder. In other embodiments, the cover window CW may be omitted.

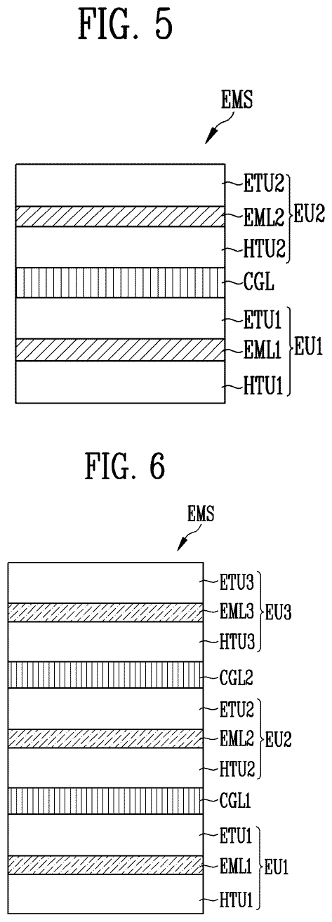

FIG. 5 is a sectional view schematically illustrating an emission structure EMS in accordance with an embodiment.

Referring to FIG. 5, the emission structure EMS may have a tandem structure in which first and second emission components EU1 and EU2 are stacked.

Each of the first and second emission components EU1 and EU2 may include at least one emission layer configured to generate light in response to current applied thereto. The first emission component EU1 may include a first emission layer EML1, a first electron transport component ETU1, and a first hole transport component HTU1. The first emission layer EML1 may be disposed between the first electron transport component ETU1 and the first hole transport component HTU1. The second emission component EU2 may include a second emission layer EML2, a second electron transport component ETU2, and a second hole transport component HTU2. The second emission layer EML2 may be disposed between the second electron transport component ETU2 and the second hole transport component HTU2.

Each of the first and second hole transport components HTU1 and HTU2 may include at least one of a hole injection layer and a hole transport layer, and may further include a hole buffer layer, an electron blocking layer, and the like, as needed. The first and second hole transport components HTU1 and HTU2 may have the same configuration or have different configurations.

Each of the first and second electron transport components ETU1 and ETU2 may include at least one of an electron injection layer and an electron transport layer, and may further include an electron buffer layer, a hole blocking layer, and the like, as needed. The first and second electron transport components ETU1 and ETU2 may have the same configuration or have different configurations.

A connection layer, which can be provided in the form of a charge generation layer CGL, may be disposed between the first emission component EU1 and the second emission component EU2 to connect the first and second emission components EU1 and EU2 to each other. In embodiments, the charge generation layer CGL may have a stacked structure including a p-dopant layer and an n-dopant layer. For example, the p-dopant layer may include a p-type dopant such as HAT-CN, TCNQ, or NDP-9, and the n-dopant layer may include alkali metal, alkaline earth metal, lanthanide metal, or a combination thereof. However, embodiments are not limited to the aforementioned example.

In embodiments, the first emission layer EML1 and the second emission layer EML2 may generate light in different colors. The light emitted from the first emission layer EML1 and the second emission layer EML2 may be mixed to be visible as white light. For instance, the first emission layer EML1 may generate light in blue, and the second emission layer EML2 may generate light in yellow. In embodiments, the second emission layer EML2 may include a stacked structure including a first sub-emission layer configured to generate light in red, and a second sub-emission layer configured to generate light in green. Light in red and light in green may be mixed to provide light in yellow. In this case, an intermediate layer configured to perform functions of transporting holes and/or blocking the transport of electrons may be further disposed between the first and second sub-emission layers.

In embodiments, the first emission layer EML1 and the second emission layer EML2 may generate light in the same color.

The emission structure EMS may be formed through a scheme such as vacuum deposition, inkjet printing, or the like, but embodiments are not limited thereto.

FIG. 6 is a sectional view schematically illustrating an emission structure EMS in accordance with an embodiment.

Referring to FIG. 6, the emission structure EMS may have a tandem structure in which first to third emission components EU1 and EU3 are stacked.

Each of the first to third emission components EU1 to EU3 may include an emission layer configured to generate light in response to current applied thereto. The first emission component EU1 may include a first emission layer EML1, a first electron transport component ETU1, and a first hole transport component HTU1. The first emission layer EML1 may be disposed between the first electron transport component ETU1 and the first hole transport component HTU1. The second emission component EU2 may include a second emission layer EML2, a second electron transport component ETU2, and a second hole transport component HTU2. The second emission layer EML2 may be disposed between the second electron transport component ETU2 and the second hole transport component HTU2. The third emission component EU3 may include a third emission layer EML3, a third electron transport component ETU3, and a third hole transport component HTU3. The third emission layer EML3 may be disposed between the third electron transport component ETU3 and the third hole transport component HTU3.

Each of the first to third hole transport components HTU1 to HTU3 may include at least one of a hole injection layer and a hole transport layer, and may further include a hole buffer layer, an electron blocking layer, and the like, as needed. The first to third hole transport components HTU1 to HTU3 may have the same configuration or have different configurations.

Each of the first to third electron transport components ETU1 to ETU3 may include at least one of an electron injection layer and an electron transport layer, and may further include an electron buffer layer, a hole blocking layer, and the like, as needed. The first to third electron transport components ETU1 to ETU3 may have the same configuration or have different configurations.

A first charge generation layer CGL1 may be disposed between the first emission component EU1 and the second emission component EU2. A second charge generation layer CGL2 may be disposed between the second emission component EU2 and the third emission component EU3.

In embodiments, the first to third emission layers EML1 to EML3 may generate light in different colors. Light emitted from the first to third emission layers EML1 to EML3 may be mixed to be visible as white light. For example, the first emission layer EML1 may generate light in blue, the second emission layer EML2 may generate light in green, and the third emission layer EML3 may generate light in red.

In other embodiments, two or more emission layers among the first to third emission layers EML1 to EML3 may generate light in the same color.

Unlike the case illustrated in FIGS. 5 and 6, the emission structure EMS may include a single emission component.

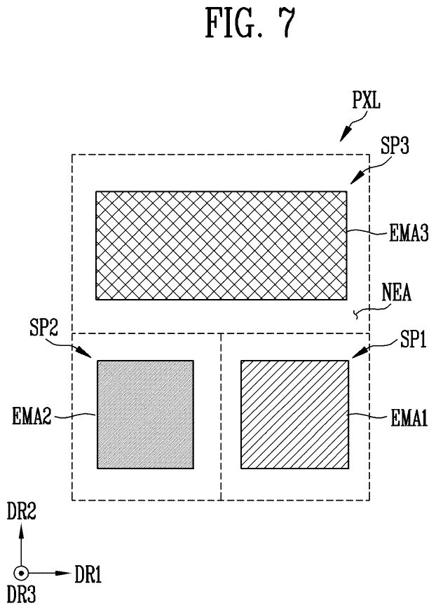

FIG. 7 is a plan view schematically illustrating a pixel PXL in accordance with an embodiment.

Referring to FIG. 7, the pixel PXL may include first to third sub-pixels SP1 to SP3.

The first sub-pixel SP1 may include a first emission area EMA1 and a non-emission area NEA formed around the first emission area EMA1. The second sub-pixel SP2 may include a second emission area EMA2 and a non-emission area NEA formed around the second emission area EMA2. The third sub-pixel SP3 may include a third emission area EMA3 and a non-emission area NEA formed around the third emission area EMA3.

The first emission area EMA1 may be an area where light is emitted from a portion of the emission structure EMS (refer to FIG. 4) that corresponds to the first sub-pixel SP1. The second emission area EMA2 may be an area where light is emitted from a portion of the emission structure EMS that corresponds to the second sub-pixel SP2. The third emission area EMA3 may be an area where light is emitted from a portion of the emission structure EMS that corresponds to the third sub-pixel SP3. As described with reference to FIG. 4, each emission area may be understood as the opening OP of the pixel defining layer PDL corresponding to each of the first to third sub-pixels SP1 to SP3.

Each of the first to third emission areas EMA1 to EMA3 may have a quadrangular shape. For example, each corner of the first to third emission areas EMA1 to EMA3 may be right-angled. The term “quadrangular shape” may mean a shape of either a rectangle or a square.

The first sub-pixel SP1 and the second sub-pixel SP2 may be arranged in the first direction DR1. The third sub-pixel SP3 may be disposed in the second direction DR2 with respect to each of the first and second sub-pixels SP1 and SP2. However, embodiments are not limited to the aforementioned example. For example, the first to third sub-pixels SP1 to SP3 may be arranged in the first direction DR1.

The first sub-pixel SP1 may have a larger surface area than the second sub-pixel SP2. The third sub-pixel SP3 may have a larger surface area than the first sub-pixel SP1. Therefore, the first emission area EMA1 may have a larger surface area than the second emission area EMA2. The third emission area EMA3 may have a larger surface area than the first emission area EMA1. However, embodiments are not limited to the aforementioned example. For example, the first and second sub-pixels SP1 and SP2 may have substantially the same surface area. The third sub-pixel SP3 may have a larger surface area than each of the first and second sub-pixels SP1 and SP2. As such, the surface areas of the first to third sub-pixels SP1 to SP3 may be changed in various ways depending on embodiments.

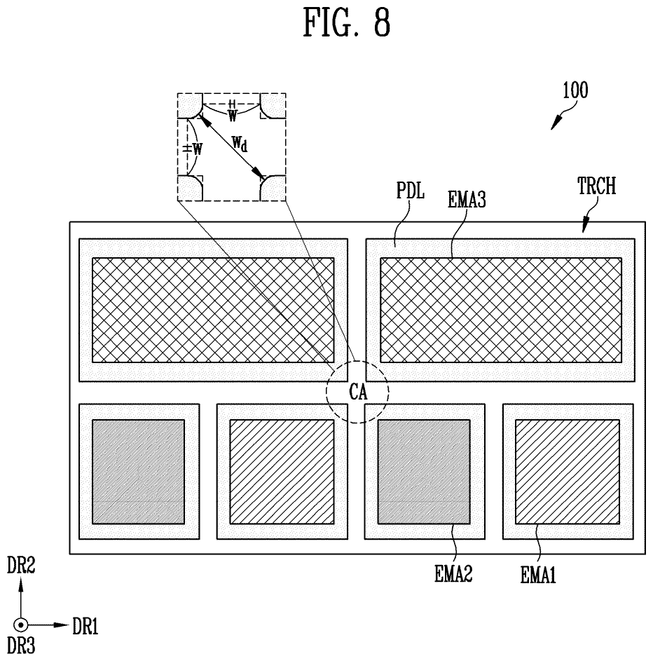

FIG. 8 is a plan view schematically illustrating a display device 100 including pixels PXL of FIG. 7.

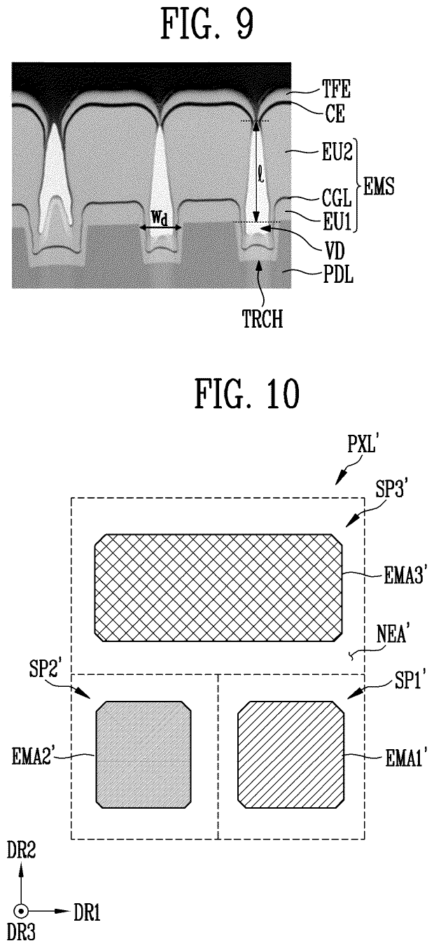

Referring to FIG. 8, the display device 100 may include a pixel defining layer PDL that overlaps the non-emission area NEA (refer to FIG. 7). The pixel defining layer PDL may include a trench TRCH that is integrally formed to enclose the first to third emission areas EMA1 to EMA3. Referring to FIG. 9, the trench TRCH may refer to a structure that is formed in the pixel defining layer PDL and partially penetrates the pixel defining layer PDL, but embodiments are not limited thereto.

The trench TRCH may be patterned by etching a portion of the pixel defining layer PDL between the first to third emission areas EMA1 to EMA3. Hence, the trench TRCH may be positioned between the first to third emission areas EMA1 to EMA3. For example, the trench TRCH may be positioned between the first emission area EMA1 and the second emission area EMA2. For instance, the trench TRCH may be positioned between the first emission area EMA1 and the third emission area EMA3. For example, the trench TRCH may be positioned between the second emission area EMA2 and the third emission area EMA3. For example, the trench TRCH may be positioned between adjacent third emission areas EMA3. In other words, one trench TRCH may be positioned between the first to third emission areas EMA1 to EMA3, with space from the first to third emission areas EMA1 to EMA3.

The trench TRCH may be patterned along peripheries of the first to third emission areas EMA1 to EMA3 to enclose the first to third emission areas EMA1 to EMA3. For example, the trench TRCH with a certain width w may be patterned along the peripheries of the first to third emission areas EMA1 to EMA3 each having right-angled corners. In this case, an intersection area CA where portions of the trench TRCH intersect with each other may be formed. For the sake of explanation convenience, in FIG. 8, the intersection area CA of the trench TRCH formed in a central portion is illustrated as a representative example, and reference symbols for the other intersection areas are omitted.

Ideally, the pixel defining layer PDL adjacent to the intersection area CA of the trench TRCH may have a rectangular shape. However, referring to an enlargement of the intersection area CA, the pixel defining layer PDL adjacent to the intersection area CA has substantially a rounded shape because it is difficult to implement right-angled patterning in the manufacturing process. Accordingly, a diagonal width wa of the trench TRCH in the intersection area CA may increase.

FIG. 9 is a sectional view schematically illustrating the display device of FIG. 8.

Referring to FIG. 9, due to the trench TRCH, a discontinuous portion such as a void VD may be formed in the emission structure EMS. Some of the multiple layers stacked in the emission structure EMS may be interrupted or bent by the void VD. For example, the charge generation layer CGL included in the emission structure EMS may be interrupted by the void VD. Consequently, lateral leakage current may be prevented from flowing between adjacent sub-pixels SP (refer to FIG. 1) through the charge generation layer CGL.

As the width of the trench TRCH increases, a length l of the void VD may increase. For example, as the diagonal width wa of the trench TRCH in the intersection area CA (refer to FIG. 8) increases, the length l of the void VD may increase. In this case, unlike the embodiments described above, the charge generation layer CGL integrally extends without interruption. Hence, lateral leakage current may flow between adjacent sub-pixels SP. Furthermore, the void VD may grow to reach the cathode electrode CE and thus cause a disconnection in the cathode electrode CE. In addition, the void VD may grow to reach the encapsulation layer TFE, thus leading to a disconnection in the encapsulation layer TFE, or occurrence of defects such as seams in the encapsulation layer TFE.

FIG. 10 is a plan view schematically illustrating a pixel in accordance with an embodiment.

With regard to FIG. 10, the explanation of contents overlapping that of FIG. 7 is simplified or omitted.

Referring to FIG. 10, the pixel PXL′ may include first to third sub-pixels SP1′ to SP3′.

The first sub-pixel SP1′ may include a first emission area EMA1′ and a non-emission area NEA′ formed around the first emission area EMA1′. The second sub-pixel SP2′ may include a second emission area EMA2′ and a non-emission area NEA′ formed around the second emission area EMA2′. The third sub-pixel SP3′ may include a third emission area EMA3′ and a non-emission area NEA′ formed around the third emission area EMA3′.

Each of the first to third emission areas EMA1′ to EMA3′ may have an octagonal shape. For example, each corner of the first to third emission areas EMA1′ to EMA3′ may be chamfered. Hence, the sizes of the first to third emission areas EMA1′ to EMA3′ illustrated in FIG. 10 may be less than the sizes of the first to third emission areas EMA1 to EMA3 illustrated in FIG. 7. Furthermore, the size of the non-emission area NEA′ illustrated in FIG. 10 may be greater than the size of the non-emission area NEA illustrated in FIG. 7.

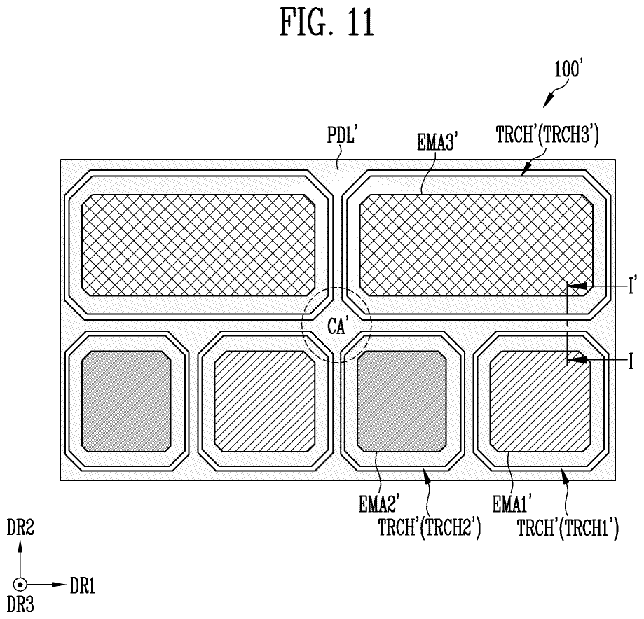

FIG. 11 is a plan view schematically illustrating a display device 100′ including pixels of FIG. 10.

Referring to FIG. 11, the display device 100′ may include a pixel defining layer PDL′ that overlaps the non-emission area NEA′ (refer to FIG. 10). The pixel defining layer PDL′ may include trenches TRCH that are individually formed to respectively enclose the first to third emission areas EMA1′ to EMA3′.

The trenches TRCH′ may be differentiated into first trenches TRCH1′, second trenches TRCH2′, or third trenches TRCH3′ depending on locations. For example, each of the first trenches TRCH1′ may enclose the corresponding first emission area EMA1′. For example, each of the second trenches TRCH2′ may enclose the corresponding second emission area EMA2′. For example, each of the third trenches TRCH3′ may enclose the corresponding third emission area EMA3′.

The trenches TRCH′ may be patterned by etching portions of the pixel defining layer PDL between the first to third emission areas EMA1′ to EMA3′. Hence, the trenches TRCH′ may be positioned between the first to third emission areas EMA1′ to EMA3′. For example, each of the first trenches TRCH1′ and each of the second trenches TRCH2′ may be positioned between the first emission area EMA1′ and the second emission area EMA2′. For example, each of the first trenches TRCH1′ and each of the third trenches TRCH3′ may be positioned between the first emission area EMA1′ and the third emission area EMA3′. For example, each of the second trenches TRCH2′ and each of the third trenches TRCH3′ may be positioned between the second emission area EMA2′ and the third emission area EMA3′. For example, each of the third trenches TRCH3′ may be positioned between adjacent third emission areas EMA3′. In other words, two trenches TRCH′ may be positioned between the first to third emission areas EMA1′ to EMA3′, with space from the first to third emission areas EMA1′ to EMA3′.

Corners of the trenches TRCH′ may be chamfered. For example, each corner of the first to third trenches TRCH1′ to TRCH3′ may be chamfered. As illustrated in FIG. 11, each of the first to third trenches TRCH1′ to TRCH3′ may be patterned in an octagonal shape on outer and inner surfaces thereof.

The trenches TRCH′ may be patterned along peripheries of the first to third emission areas EMA1′ to EMA3′ to enclose the first to third emission areas EMA1′ to EMA3′. For example, each of the first trenches TRCH1′ may be patterned along the periphery of the corresponding first emission area EMA1′ with the chamfered corners. For example, each of the second trenches TRCH2′ may be patterned along the periphery of the corresponding second emission area EMA2′ with the chamfered corners. For example, each of the third trenches TRCH3′ may be patterned along the periphery of the corresponding third emission area EMA3′ with the chamfered corners.

In this case, an intersection area CA′ where portions of the pixel defining layer PDL′ intersect with each other may be formed. For the sake of explanation convenience, in FIG. 11, the intersection area CA′ formed in a central portion is illustrated as a representative example, and reference symbols for the other intersection areas are omitted.

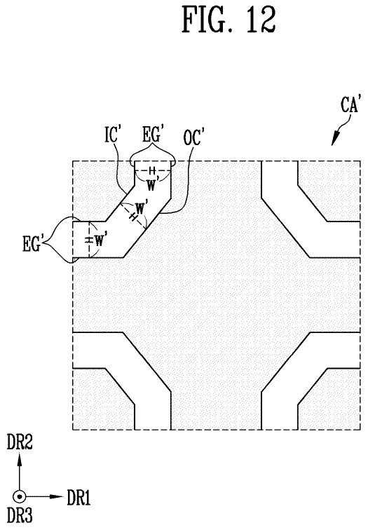

FIG. 12 is an enlarged view of the intersection area CA′ of FIG. 11.

Referring to FIG. 12, the corners of the trenches TRCH′ (refer to FIG. 11) may include an inner corner IC′ and an outer corner OC′. In an embodiment, the inner corners IC′ and the outer corners OC′ of the trenches TRCH′ may be chamfered. Therefore, the corners and edges EG′ of the trenches TRCH′ may have an identical width w′. As such, as each of the trenches TRCH′ encloses the corresponding emission area and has the chamfered inner corners IC′ and the chamfered outer corners OC′, the intersection area CA′ of the pixel defining layer, rather than the intersection area CA (refer to FIG. 8) of the trench, may be formed. Therefore, each of the trenches TRCH′ may have the uniform width w′ along the periphery of the corresponding emission area.

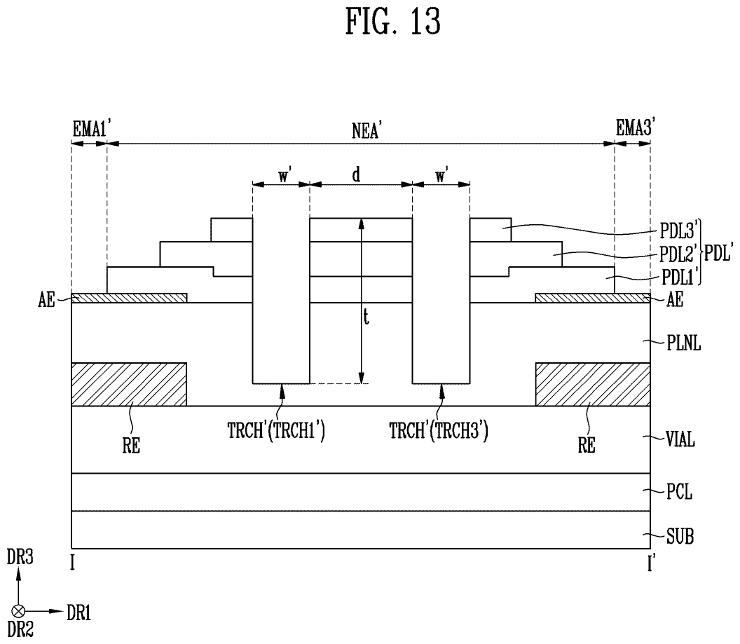

FIG. 13 is a sectional view taken along line I-l′ of FIG. 11.

Referring to FIG. 13, the pixel circuit layer PCL may be disposed on the substrate SUB. A via layer VIAL may be disposed on the pixel circuit layer PCL.

The via layer VIAL may cover the pixel circuit layer PCL, and have an overall even surface. The via layer VIAL is configured to planarize stepped portions on the pixel circuit layer PCL. The via layer VIAL may include at least one of silicon oxide (SiOₓ), silicon nitride (SiNₓ), and silicon carbon nitride (SiCN), but embodiments are not limited thereto.

Reflective electrodes RE may be disposed on the via layer VIAL. Each of the reflective electrodes RE may function as a full mirror provided to reflect light emitted from the emission structure EMS (refer to FIG. 4) toward the display surface. The reflective electrodes RE may include metallic materials suitable for reflecting light. For example, the reflective electrodes RE may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy of two or more materials selected from among the aforementioned materials, but embodiments are not limited thereto.

To planarize stepped portions between the reflective electrodes RE, a planarization layer PLNL may be disposed on the via layer VIAL and the reflective electrodes RE. The planarization layer PLNL may cover overall surfaces of the reflective electrodes RE and the via layer VIAL, and may have an even surface. In embodiments, the planarization layer PLNL may be omitted.

On the planarization layer PLNL, anode electrodes AE may be disposed for the respective reflective electrodes RE. The anode electrodes AE may be respectively connected to the corresponding reflective electrodes RE through a via (not illustrated). In embodiments, the anode electrodes AE may include at least one of transparent conductive materials such as indium tin oxide (ITO), indium zinc oxide (IZO), zinc oxide (ZnOx), indium gallium zinc oxide (IGZO), and indium tin zinc oxide (ITZO). However, the material of the anode electrodes AE is not limited to the foregoing example. For example, the anode electrodes AE may include titanium nitride.

The pixel defining layer PDL′ may be disposed on portions of the anode electrodes AE and the planarization layer PLNL. The pixel defining layer PDL′ may be disposed in the non-emission area NEA′ and define each emission area.

In embodiments, the pixel defining layer PDL′ may include a plurality of inorganic insulating layers. Each of the inorganic insulating layers may include at least one of silicon oxide (SiOₓ) and silicon nitride (SiNₓ). For example, the pixel defining layer PDL′ may include first to third inorganic insulating layers PDL1′ to PDL3′ that are successively stacked. The first to third inorganic insulating layers PDL1′ to PDL3′ may respectively include silicon nitride, silicon oxide, and silicon nitride, but embodiments are not limited thereto. The first to third inorganic insulating layers PDL1′ to PDL3′ may have a stepped cross-section.

In embodiments, the trenches TRCH′ may pass through the pixel defining layer PDL′ and partially penetrate the planarization layer PLNL. However, embodiments are not limited to the aforementioned example. In embodiments, the trenches TRCH′ may pass through the pixel defining layer PDL′ and the planarization layer PLNL, and partially penetrate the via layer VIAL. For example, the trenches TRCH′ may partially penetrate the pixel defining layer PDL′.

In embodiments, the width w′ of the trenches TRCH′ may range from 80 nm to 150 nm. A thickness t of the trenches TRCH′ may range from 300 nm to 1000 nm. A distance d between the trenches TRCH′ may range from 100 nm to 300 nm.

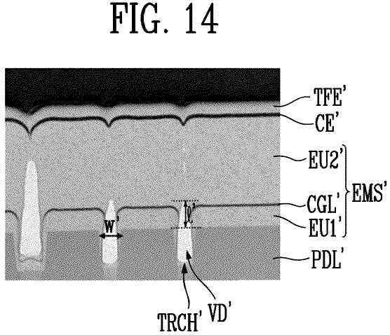

FIG. 14 is a sectional view schematically illustrating the display device of FIG. 11.

Referring to FIG. 14, due to the trench TRCH′, a discontinuous portion such as a void VD′ may be formed in the emission structure EMS′. Because the trench TRCH′ has the uniform width w′ along the periphery of each emission area, a width (or a diagonal width) of each corner of the trench TRCH′ in the intersection area CA′ (refer to FIG. 11) of the pixel defining layer does not increase. Hence, a length l′ of the void VD′ does not also increase. Therefore, the charge generation layer CGL′ included in the emission structure EMS' may have a discontinuous portion that overlaps at least a portion of the trench TRCH′. In other words, the charge generation layer CGL′ is interrupted by the void VD′ rather than integrally extending. As a result, lateral leakage current can be prevented from flowing between adjacent sub-pixels SP (refer to FIG. 1) through the charge generation layer CGL′. Furthermore, because the length l′ of the void VD′ is relatively short, the void VD′ does not grow to reach the cathode electrode CE′. Hence, the cathode electrode CE′ may be continuously formed on the emission structure EMS' without being disconnected. In addition, the void VD′ does not grow to reach the encapsulation layer TFE′. Therefore, the encapsulation layer TFE is not interrupted, and may be evenly formed without occurrence of defects such as seams in the encapsulation layer TFE.

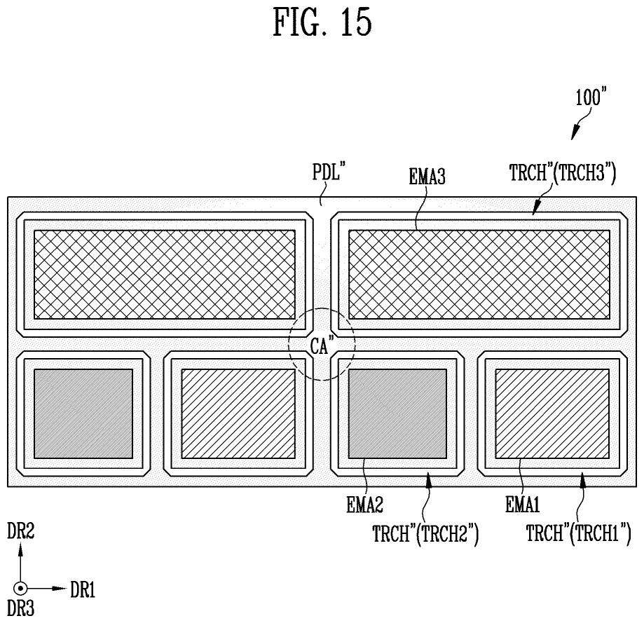

FIG. 15 is a plan view schematically illustrating a display device 100″ including pixels PXL of FIG. 7.

Referring to FIG. 15, the display device 100″ may include a pixel defining layer PDL″ that overlaps the non-emission area NEA (refer to FIG. 7). The pixel defining layer PDL″ may include trenches TRCH″ that are individually formed to respectively enclose the first to third emission areas EMA1 to EMA3. As illustrated in FIG. 15, the display device 100″ may include the first to third emission areas EMA1 to EMA3 with right-angled corners, thus leading to an increase in opening ratio, thereby enhancing emission efficiency.

The trenches TRCH″ may be differentiated into first trenches TRCH1″, second trenches TRCH2″, or third trenches TRCH3″ depending on locations. For example, each of the first trenches TRCH1″ may enclose the corresponding first emission area EMA1. For example, each of the second trenches TRCH2″ may enclose the corresponding second emission area EMA2. For example, each of the third trenches TRCH3″ may enclose the corresponding third emission area EMA3.

The trenches TRCH″ may be patterned by etching portions of the pixel defining layer PDL″ between the first to third emission areas EMA1 to EMA3. Hence, the trenches TRCH″ may be positioned between the first to third emission areas EMA1 to EMA3. For example, each of the first trenches TRCH1″ and each of the second trenches TRCH2″ may be positioned between the first emission area EMA1 and the second emission area EMA2. For example, each of the first trenches TRCH1″ and each of the third trenches TRCH3″ may be positioned between the first emission area EMA1 and the third emission area EMA3. For example, each of the second trenches TRCH2″ and each of the third trenches TRCH3″ may be positioned between the second emission area EMA2 and the third emission area EMA3. For example, each of the third trenches TRCH3″ may be positioned between adjacent third emission areas EMA3. In other words, two trenches TRCH″ may be positioned between the first to third emission areas EMA1 to EMA3, with space from the first to third emission areas EMA1 to EMA3.

Corners of the trenches TRCH″ may be chamfered. For example, each corner of the first to third trenches TRCH1″ to TRCH3″ may be chamfered. As illustrated in FIG. 15, an outer side of each of the first to third trenches TRCH1″ to TRCH3″ may be patterned in an octagonal shape, and an inner side thereof may be patterned in a quadrangular shape.

The trench TRCH″ may be patterned along peripheries of the first to third emission areas EMA1 to EMA3 to enclose the first to third emission areas EMA1 to EMA3. For example, each of the first trenches TRCH1″ may be patterned along the periphery of the corresponding first emission area EMA1 with the right-angled corners. For example, each of the second trenches TRCH2″ may be patterned along the periphery of the corresponding second emission area EMA2 with the right-angled corners. For example, each of the third trenches TRCH3″ may be patterned along the periphery of the corresponding third emission area EMA3 with the right-angled corners.

In this case, an intersection area CA″ where portions of the pixel defining layer PDL″ intersect with each other may be formed. For the sake of explanation convenience, in FIG. 15, the intersection area CA″ formed in a central portion is illustrated as a representative example, and reference symbols for the other intersection areas are omitted.

FIG. 16 is an enlarged view of the intersection area CA″ of FIG. 15 in accordance with an embodiment.

Referring to FIG. 16, the corners of the trenches TRCH″ (refer to FIG. 15) may include an inner corner IC″ and an outer corner OC″.

In an embodiment, the outer corner OC″ of each of the trenches TRCH″ may be chamfered, and the inner corner IC″ may be patterned in a right-angled shape.

In an embodiment, the corners and edges EG″ of the trenches TRCH″ may have an identical width w″. In this case, the width w″ of the edge EG″ of each of the trenches TRCH″ may be less than a maximum width wₘ between the inner corner IC″ and the outer corner OC″. As such, as each of the trenches TRCH″ encloses the corresponding emission area and has the chamfered outer corners OC″, the intersection area CA″ of the pixel defining layer, rather than the intersection area CA (refer to FIG. 8) of the trench, may be formed. Accordingly, a width (or a diagonal width) of each corner of the trenches TRCH″ in the intersection area CA″ does not increase, and each corner of the trenches TRCH″ may have the same width w″ as that of the edge EG″. Consequently, lateral leakage current described above may be prevented from flowing, the cathode electrode CE (refer to FIG. 4) may not be disconnected, and defects such as seams may not occur in the encapsulation layer TFE (refer to FIG. 4).

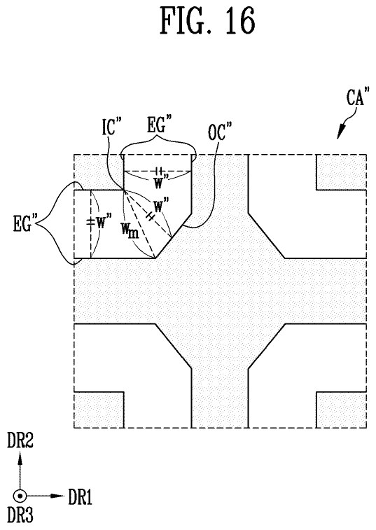

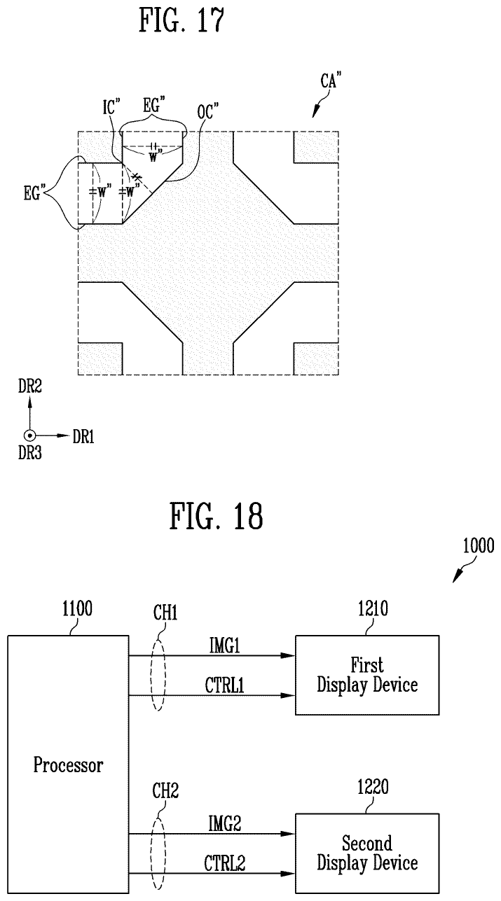

FIG. 17 is an enlarged view of the intersection area CA″ of FIG. 15 in accordance with an embodiment. With regard to FIG. 17, the explanation of contents overlapping that of FIG. 16 is simplified or omitted.

Referring to FIG. 17, a width (or a diagonal width) of each corner of the trenches TRCH″ may be less than the width w″ of the edge EG″. In this case, the width w″ of the edge EG″ of each of the trenches TRCH″ may be the same as the maximum width w″ between the inner corner IC″ and the outer corner OC″. Compared to FIG. 16, the width (or the diagonal width) of each corner of the trenches TRCH″ may be further reduced. Consequently, lateral leakage current described above may be more effectively prevented from flowing, the cathode electrode CE (refer to FIG. 4) may not be disconnected, and defects such as seams may not occur in the encapsulation layer TFE (refer to FIG. 4).

FIG. 18 is a block diagram illustrating a display system 1000 in accordance with an embodiment.

Referring to FIG. 18, the display system 1000 may include a processor 1100, and one or more display devices 1210 and 1220.

The processor 1100 may perform various tasks and operations. In embodiments, the processor 1100 may include an application processor, a graphic processor, a microprocessor, a central processing unit (CPU), and so on. The processor 1100 may be connected to the other components of the display system 1000 through a bus system to control the components.

In FIG. 18, there is illustrated the case where the display system 1000 includes the first and second display devices 1210 and 1220. The processor 1100 may be connected to the first display device 1210 through a first channel CH1, and may be connected to the second display device 1220 through a second channel CH2.

The processor 1100 may transmit first image data IMG1 and a first control signal CTRL1 to the first display device 1210 through the first channel CH1. The first display device 1210 may display an image based on the first image data IMG1 and the first control signal CTRL1. The first display device 1210 may be configured in the same manner as the display device 100 described with reference to FIG. 1. In this case, the first image data IMG1 and the first control signal CTRL1 may be provided as the input image data IMG and the control signal CTRL of FIG. 1, respectively.

The processor 1100 may transmit second image data IMG2 and a second control signal CTRL2 to the second display device 1220 through the second channel CH2. The second display device 1220 may display an image based on the second image data IMG2 and the second control signal CTRL2. The second display device 1220 may be configured in the same manner as the display device 100 described with reference to FIG. 1. In this case, the second image data IMG2 and the second control signal CTRL2 may be provided as the input image data IMG and the control signal CTRL of FIG. 1, respectively.

The display system 1000 may include computing systems that provide an image display function, such as a portable computer, a mobile phone, a smart phone, a tablet personal computer (tablet PC), a smart watch, a watch phone, a portable multimedia player, a navigation system, and an ultra mobile personal computer (UMPC). Furthermore, the display system 1000 may include at least one of a head mounted display (HMD), a virtual reality (VR) device, a mixed reality (MR) device, and an augmented reality (AR) device.

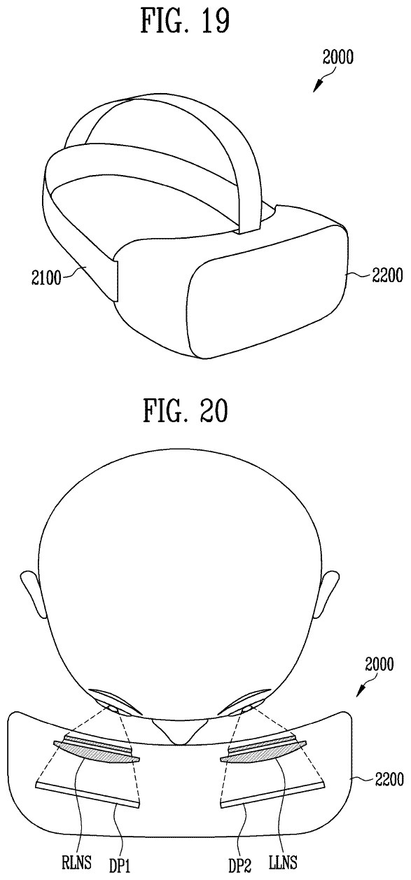

FIG. 19 is a perspective diagram illustrating an application example of the display system 1000 of FIG. 18.

Referring to FIG. 19, the display system 1000 of FIG. 18 may be applied to a head mounted display device 2000. The head mounted display device 2000 may be a wearable electronic device, which can be worn on the head of the user.

The head mounted display 2000 may include a head mounted band 2100 and a display device reception casing 2200. The head mounted band 2100 may be connected to the display device reception casing 2200. The head mounted band 2100 may include a horizontal band and/or a vertical band to fasten the head mounted display 2000 to the head of the user. The horizontal band may enclose the sides of the head of the user, and the vertical band may enclose the top of the head of the user. However, embodiments are not limited to the aforementioned example. For example, the head mounted band 2100 may be implemented in the form of eyeglass frames, a helmet, and so on.

The display device reception casing 2200 may receive the first and second display devices 1210 and 1220 of FIG. 18. The display device reception casing 2200 may further receive the processor 1100 of FIG. 18.

FIG. 20 is a diagram illustrating a head mounted display device 2000 of FIG. 19 that is worn on a user.

Referring to FIG. 20, the first display panel DP1 of the first display device 1210 and the second display panel DP2 of the second display device 1220 are disposed in the head-mounted display device 2000. The head mounted display 2000 may further include one or more lenses LLNS and RLNS.

In the display device reception casing 2200, the right-eye lens RLNS may be positioned between the first display panel DP1 and the right eye of the user. In the display device reception casing 2200, the left-eye lens LLNS may be positioned between the second display panel DP1 and the left eye of the user.

An image outputted from the first display panel DP1 can be viewed by the right eye of the user through the right-eye lens RLNS. The right lens RLNS may refract light emitted from the first display panel DP1 toward the right eye of the user. The right-eye lens RLNS may perform an optical function to adjust a viewing distance between the first display panel DP1 and the right eye of the user.

An image outputted from the second display panel DP2 can be viewed by the left eye of the user through the left-eye lens LLNS. The left lens LLNS may refract light emitted from the second display panel DP2 toward the left eye of the user. The left-eye lens LLNS may perform an optical function to adjust a viewing distance between the second display panel DP2 and the left eye of the user.

In embodiments, each of the right-eye lens RLNS and the left-eye lens LLNS may include an optical lens having a pancake-shaped cross-section. In embodiments, each of the right-eye lens RLNS and the left-eye lens LLNS may include a multi-channel lens including sub-areas having different optical characteristics. In this case, each display panel may output images respectively corresponding to sub-areas of the multi-channel lens. The output images may be viewed to the user through the corresponding sub-areas.

In accordance with embodiments, trenches with chamfered corners may be formed in a pixel defining layer, thus leading to a reduction in the size (or length) of a void that is formed during a stacking process of an emission structure. Accordingly, undesired connection of a charge generation layer may be prevented, so that lateral leakage current can be prevented from flowing between sub-pixels. Furthermore, disconnection of a cathode electrode and defects in an encapsulation layer may be prevented. As a result, the reliability of a display device can be enhanced.

However, effects of the present disclosure are not limited to the above-described effects, and various modifications are possible without departing from the spirit and scope of the present disclosure.

Although specific embodiments and application examples have been described, it should be noted that other embodiments and modifications may be derived from the disclosure provided. Accordingly, the concepts of the present disclosure are not limited to the foregoing embodiments, but rather to the broader scope of the presented claims and various obvious modifications and equivalent arrangements.

The embodiments described in detail above are provided to explain the present disclosure, but it should be noted that the embodiments are not intended to limit the scope of the present disclosure. It should be understood by those skilled in the art that various changes, substitutions, and alternations may be made herein without departing from the scope of the disclosure as defined by the following claims.

The scope of the present disclosure is not limited by detailed descriptions of the present specification, and should be defined by the accompanying claims. Furthermore, all changes or modifications of the present disclosure derived from the meanings and scope of the claims, and equivalents thereof should be construed as being included in the scope of the present disclosure.

What is claimed is:

1. A display device comprising:
pixels each including emission areas and a non-emission area adjacent to the emission areas; and
a pixel defining layer overlapping the non-emission area, the pixel defining layer including trenches enclosing the respective emission areas and spaced apart from each other,
wherein a corner of each of the trenches is chamfered.

2. The display device according to claim 1, wherein an inner corner and an outer corner of each of the trenches are chamfered.

3. The display device according to claim 1, wherein a width of an edge of each of the trenches is identical to a width of the corner of each of the trenches.

4. The display device according to claim 3, wherein the width ranges from 80 nm to 150 nm.

5. The display device according to claim 1, wherein a thickness of each of the trenches ranges from 300 nm to 1000 nm.

6. The display device according to claim 1, wherein a distance between the trenches ranges from 100 nm to 300 nm.

7. The display device according to claim 1, wherein a corner of each of the emission areas is chamfered.

8. The display device according to claim 1, wherein a corner of each of the emission areas is right-angled.

9. The display device according to claim 8, wherein an inner corner of each of the trenches is right-angled, and an outer corner of each of the trenches is chamfered.

10. The display device according to claim 9, wherein a width of an edge of each of the trenches is identical to a width of the corner of each of the trenches.

11. The display device according to claim 10, wherein the width of the edge of each of the trenches is less than a maximum width between the inner corner and the outer corner of each of the trenches.

12. The display device according to claim 9, wherein a width of an edge of each of the trenches is different from a width of the corner of each of the trenches.

13. The display device according to claim 12, wherein the width of the edge of each of the trenches is greater than the width of the corner of each of the trenches.

14. The display device according to claim 12, wherein the width of the edge of each of the trenches is identical to a maximum width between the inner corner and the outer corner of each of the trenches.

15. The display device according to claim 1, wherein the emission areas include a first emission area configured to emit light in a first color, a second emission area configured to emit light in a second color, and a third emission area configured to emit light in a third color.

16. The display device according to claim 15, wherein the first emission area and the second emission area are arranged in a first direction, and the third emission area is arranged in a second direction with respect to the first emission area and the second emission area.

17. The display device according to claim 1, further comprising
anode electrodes to which openings of the pixel defining layer extend;
an emission structure disposed on the anode electrodes and the pixel defining layer; and
a cathode electrode disposed on the emission structure.

18. The display device according to claim 17, wherein the emission structure comprises:
a first emission component including a first hole transport component, a first electron transport component, and a first emission layer disposed between the first hole transport component and the first electron transport component;
a second emission component including a second hole transport component, a second electron transport component, and a second emission layer disposed between the second hole transport component and the second electron transport component; and
a charge generation layer disposed between the first emission component and the second emission component.

19. The display device according to claim 18, wherein the charge generation layer includes a discontinuous portion overlapping at least a portion of each of the trenches.

20. The display device according to claim 17, wherein the cathode electrode is continuously disposed on the emission structure.
